(19) United States
(12) Patent Application Publication
(10) Pub. No.: US 2018/0312964 A1
(43) Pub. Date: Nov. 1, 2018

(54) DEVICE, METHOD AND USE FOR THE COATING OF LENSES

(71) Applicant: Schneider GmbH & Co. KG, Fronhausen (DE)

(72) Inventors: Gunter Schneider, Marburg (DE); Stephan Huttenhuis, Niederweimar (DE); Markus Fuhr, Erlensee (DE)

(73) Assignee: Schneider GmbH & Co. KG, Fronhausen (DE)

(21) Appl. No.: 15/736,979

(22) PCT Filed: Jun. 16, 2016
(86) PCT No.: PCT/EP2016/025062

§ 371 Date: Dec. 15, 2017

(30) Foreign Application Priority Data
Jun. 16, 2015 (EP) 15001772.1
Jun. 17, 2015 (EP) 15001787.9
Sep. 8, 2015 (EP) 15020153.1

(51) Int. Cl. C23C 14/50; C23C 14/35

(52) U.S. Cl. CPC C23C 14/505; C23C 14/35

(57) ABSTRACT

A device and a method for the coating of lenses. The lenses which are to be coated are arranged in pairs over parallel tubular targets such that they each overlap both a homogeneous and an inhomogeneous removal region of the target and the lenses rotated so that an especially uniform coating can be achieved.

### BACKGROUND OF THE INVENTION

### Field of the Invention

The present invention relates to a device for coating of lenses a, a method for coating of lenses, as well as a method of using a tubular target for coating of lenses.

The present invention relates in general to the coating of lenses by sputtering which is also called cathode sputtering. In doing so, atoms are separated from a solid, the so-called target, by the impact of high-energy ions, and pass into a gaseous phase. In particular, the present invention relates to so-called magnetron sputtering in which in addition to an applied electrical field there is also a magnetic field behind the cathode and/or the target.

In practice it is difficult to achieve a uniform coating of the lens which is to be coated, even if the prior art discloses many different devices and methods for sputtering.

### Description of Related Art

German Patent DE 40 10 495 C2 discloses a device for coating of a substrate with materials by sputtering, the substrate being able to rotate around a stationary axis and two targets which are kept tilted to the substrate surface being assigned to the substrate. Here, a uniform coating cannot be achieved or at best can only be achieved with great difficulty.

German Utility Model DE 295 05 497 U1 and corresponding U.S. Pat. Nos. 5,911,861 and 6,123,814 disclose a coating station for coating of lenses by sputtering, the lenses being moved in a planetary arrangement over a flat sputtering source. Here, the construction effort is considerable and the feed of the coating station with the lenses to be coated is complex. Furthermore, an optimum uniform coating cannot be achieved or can only be achieved with great difficulty.

International Patent Application Publication WO 03/023813 A1 discloses an apparatus for coating of lenses by pulse magnetron sputtering, the lenses being moved linearly along the longitudinal extension of two tubular targets which run in parallel, and also rotating in doing so. Here, a uniform coating of the lenses cannot be achieved or can be achieved at best only with great difficulty.

### SUMMARY OF THE INVENTION

The object of the present invention is to provide a device and a method for the coating of lenses, a very uniform coating in particular of curved surfaces of the lenses being enabled with a simple structure and/or with simple feed.

The aforementioned object is achieved by a device and methods as disclosed herein.

According to one aspect of the present invention, the device preferably has an elongated or tubular target and the lens which is to be coated can be rotated around an axis which is stationary relative to the target. In particular, in doing so the lens cannot be moved linearly, but it is preferably a stationary arrangement, the target and the lens preferably rotating each around stationary axes. Thus at low construction effort an especially uniform coating of the lens can be achieved.

According to another aspect of the present invention, the lens which is to be coated is preferably held above a target both in a first, at least essentially homogeneous region and in a second, inhomogeneous region of a rate profile of removal of the target, and is rotated in doing so. Thus, an especially uniform coating in particular of a curved lens surface is enabled.

In particular, the lens which is to be coated is held in one end region or its vicinity over the preferably elongated or tubular target. Thus, an especially good utilization of the delivery rate which is increased just towards the end of the target and thus an improved utilization of the atomized target material can take place.

According to another aspect of the present invention, preferably two elongated and/or tubular, in particular parallel targets are used for coating of curved surfaces of lenses, the lenses being arranged in pairs over the target and, preferably, being rotated around one stationary axis. This enables a simple, compact structure, very uniform coatings of the lenses being attainable.

According to another aspect of the present invention the device preferably comprises one carrier which together with at least two lenses is interchangeable. This enables very simple and prompt feed of the device.

According to another aspect of the present invention which can likewise be implemented independently, preferably one target with an outside diameter which varies over its axial extension or longitudinal extension is used for coating of a lens. Thus, in particular the rate profile can be influenced, in particular made uniform, and/or in particular a very uniform or more uniform coating on the lens or some other coating characteristic on the lens can be achieved or facilitated.

The aforementioned aspects as well as the features and aspects of the present invention which follow from the further description can be implemented independently of one another, but also in any combination.

Further aspects, advantages and features of the present invention will become apparent from the following description of a preferred exemplary embodiment with reference to the accompanying drawings.

### BRIEF DESCRIPTION OF THE DRAWINGS

FIG. 1 shows a schematic section of a device according to the proposal for coating of lenses;

FIG. 2 shows a schematic plan view of the device;

FIG. 3 shows a schematic side view of the device with a schematically indicated rate profile; and

FIG. 4 shows a schematic plan view of the device according to FIG. 2, but with alternatively arranged lenses.

### DETAILED DESCRIPTION OF THE INVENTION

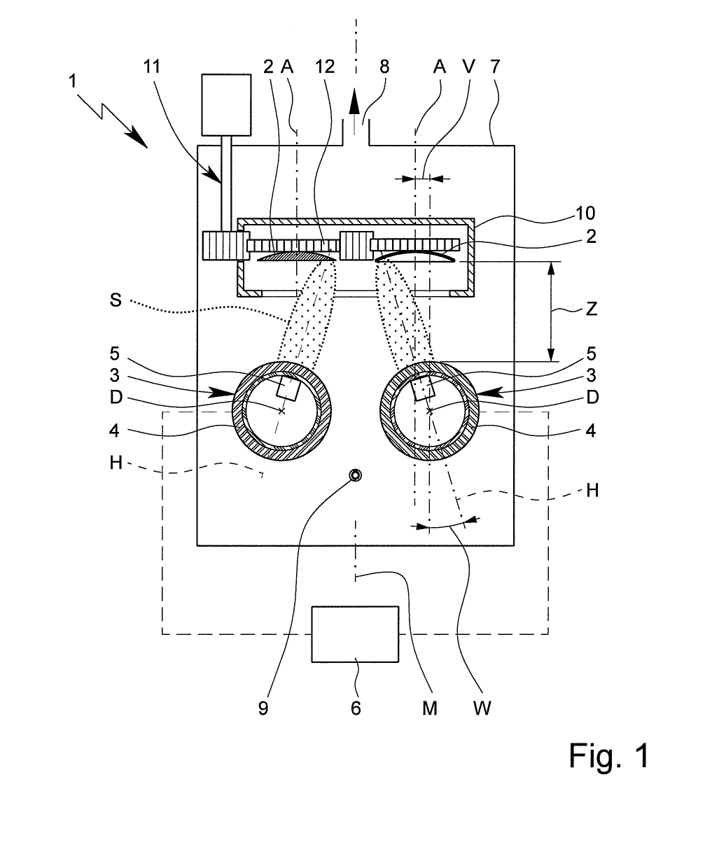

FIG. 1 shows in a very schematic section a device 1 according to the proposal for coating of lenses 2, preferably optical or ophthalmic lenses and/or eyeglass lenses, in particular of plastic.

The device 1 is designed in particular for coating of lenses 2 by sputtering, also called cathode sputtering. Especially preferably, so-called magnetron sputtering takes place. In addition to an electrically applied field, in doing so, a magnetic field is also used and/or applied; this will be explained in detail below.

Especially preferably, curved, in particular concave surfaces of the lenses 2 are coated according to the invention. One such curved surface is schematically indicated in FIG. 1 for the lens 2 which is shown on the right side. However, in principle convex surfaces or other surfaces of the lenses 2 can also be coated accordingly.

The device 1 has at least one sputtering source 3, here preferably two sputtering sources 3.

The device 1 or the respective sputtering source 3 has one target 4 whose material is removed during coating and/or sputtering and—in particular together with the other components of the gas atmosphere—forms the desired coating on the respective lens 2 or its surface which is to be coated.

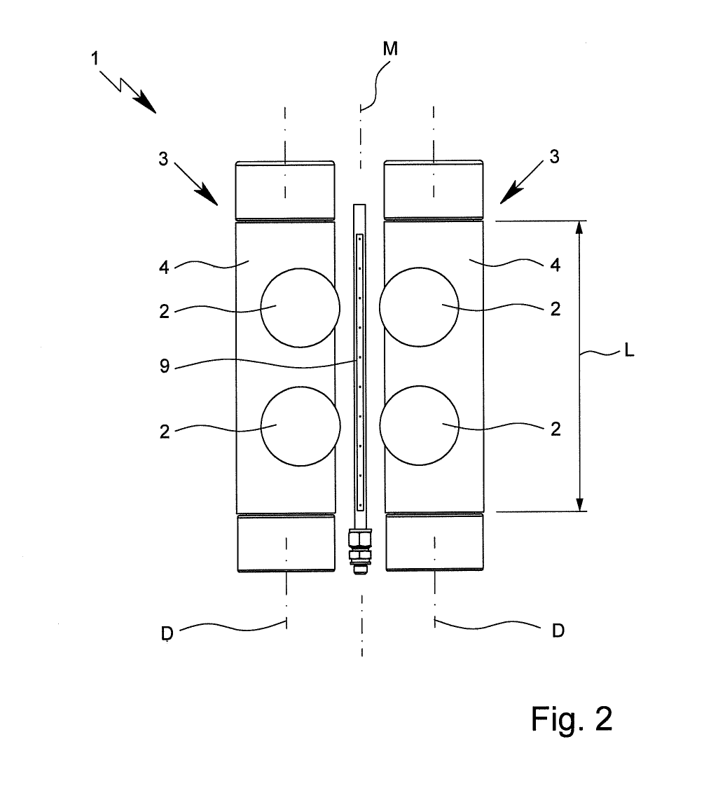

FIG. 2 shows the device 1 or sputtering sources 3 in a schematic plan view.

The sputtering sources 3 and/or targets 4 in the illustrated example are preferably made at least essentially elongated and/or tubular or cylindrical.

The targets 4 are made in particular hollow cylindrical and/or tubular.

The sputtering sources 3 and/or targets 4 are preferably arranged parallel to one another.

Preferably, the targets 4 can be turned or rotated around the axes D of rotation. The axes D of rotation run preferably in one common plane and/or in particular parallel to one another, as indicated in FIGS. 1 and 2, but alternatively can also be tilted to one another. The axes D of rotation correspond preferably to the longitudinal axes of the sputtering sources 3.

Especially preferably, the sputtering sources 3 and/or targets 4 are structurally identical and/or are built identically so that primarily only the structure of one sputtering source 3 and/or one target 4 is detailed below. However, the sputtering sources 3 and targets 4 can in principle also be made differently.

The sputtering source 3 has preferably one magnet arrangement 5 which is assigned to the respective target 4 for generating the already mentioned magnetic field and thus to a directed sputtering cloud S, as schematically indicated in FIG. 1. In particular, the magnet arrangement 5 is located under and/or in the respective target 4.

The device 1 has a voltage source 6, as indicated in FIG. 1, in order to operate the sputtering sources 3 and/or targets 4—in particular alternately—as a cathode and/or in order to be able to apply the required voltage to the sputtering sources 3 and/or targets 4 for sputtering, in particular in the form of pulses.

Especially preferably, the sputtering sources 3 and/or targets 4 are operated and/or exposed alternately with direct current (pulses). This is also called “bi-polar DC”. Alternately then one sputtering source 3 and/or target 4 is used as the cathode and the other sputtering source 3 and/or the other target 4 as the anode.

Alternatively, operation with alternating current or some other mode are possible.

Alternatively, or in addition, one or more additional or separate anodes can be used, even if this is not preferred.

The device 1 has preferably one coating chamber 7 in which the coating takes place and/or the sputtering sources 3 are located.

The preferred alternating operation of the sputtering sources 3 and/or targets 4 as cathode and anode leads to a housing-side or fixed counter-electrode not being necessary. In particular, the coating chamber 7 is not used as a counter-electrode. In this way, unwanted soiling and/or deposition of target material on the counter-electrode can be minimized and/or an especially stable method or coating can also be achieved regardless of soiling of the coating chamber 7. Accordingly, in this way required cleanings and maintenances can be reduced.

Furthermore, the targets 4 can be very easily changed. This also facilitates service.

The coating chamber 7 can be evacuated in the desired manner in particular by means of an apparatus 8 which is indicated only schematically here, such as a connection, a vacuum pump or the like.

The device 1 and/or the coating chamber 7 preferably has a schematically indicated gas supply 9, in particular in the form of a gas lance which extends into the coating space.

The device 1 has preferably one carrier 10 for holding the lenses 2, as indicated in FIG. 1.

The carrier 10 is not shown in FIG. 2 and in other figures for purposes of illustration.

The lenses 2 which are to be coated can preferably each be turned or rotated around an axis A. The device 1 and/or the carrier 10 is designed for corresponding rotary holding and in particular for corresponding driving of the lenses 2. In particular, the device 1 has a corresponding rotary drive 11 which is only schematically indicated in FIG. 1, preferably in order to drive all lenses 2 of the carrier 10 jointly.

Preferably, the carrier 10 is interchangeable together with at least two lenses 2 or all lenses 2 or here four lenses 2 which are being coated at the same time in the device 1 and/or the coating chamber 7.

In particular, the carrier 10 holds the lenses 2 such that they can be rotated—in particular around their own and/or different axes A—, especially preferably such that they are rotatably coupled. Especially preferably, the carrier 10 has a rotary coupling 12, for example via a corresponding gear, as schematically indicated in FIG. 1.

Preferably, the carrier 10 itself is not moved during the coating, but only the lenses 2 held by the carrier 10 are rotated. Preferably, the carrier 10 can be automatically coupled drivingly or by transmission or coupled in terms of drive or gear, in particular to the rotary drive 11 or the like of the device 1, upon insertion of the carrier 10 or pushing the carrier 10 into the device 1 and/or coating chamber 7.

The carrier 10 allows quick feed of the device 1 and/or the coating chamber 7 with the lenses 2 which are to be coated and/or quick removal of the coated lenses 2.

The device 1 and/or coating chamber 7 can preferably be fed with the lenses 2 to be coated and the carrier 10 via an access opening which is not shown. The access opening can be sealed in particular gas-tight preferably by means of the carrier 10 or by a closure which is not shown.

The coating chamber 7 can preferably be sealed gas-tight for coating.

The carrier 10 can preferably be used in general in devices for the coating of lenses 2, in particular therefore also in coating methods other than sputtering.

The axes D of rotation and/or longitudinal extensions L of the target 4 run preferably in a common plane, especially preferably a horizontal plane.

The lenses 2 are preferably located above the aforementioned plane.

Preferably, each lens 2 is located over an assigned target 4. The term “over” can relate to the vertical height relative to the assigned target 4 and/or to the surface of the lens 2 to be coated having at least one surface normal which intersects the target 4 and especially preferably its axis D of rotation.

Preferably, the lenses 2 are assigned in pairs to one sputtering source 3 and/or one target 4.

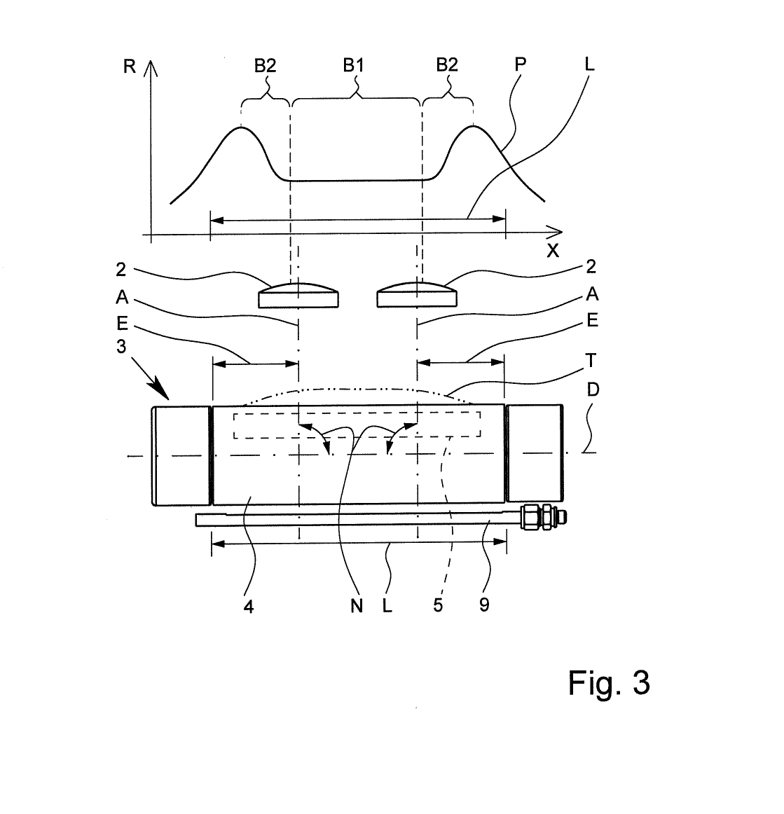

In particular, two lenses 2 are located above a common target 4 in each case, as indicated in FIG. 2 and in the schematic side view according to FIG. 3.

Especially preferably, the device 1 and/or the carrier 10 is designed for accommodating two pairs of lenses 2, therefore a total of four lenses 2, two lenses 2 being assigned to a common sputtering source 3 and/or a common target 4 in each case. The preferred arrangement and alignment of one such pair of lenses 2 which are assigned to a common target 4 are detailed below. These statements and explanations apply in particular accordingly to the other pair of lenses 2 since the device 1 and/or the arrangement of lenses 2 in the device 1 is especially preferably for the most part symmetrical with respect to a middle plane M—in FIGS. 1 and 2 the middle plane M which is standing vertically on the plane of the drawing.

The lenses 2 which are assigned to a common target 4 are preferably arranged offset in one direction parallel to the longitudinal extension L and/or axis D of rotation of the target 4. This direction is also called the X direction or X axis in particular in the diagram schematically indicated in FIG. 3.

The lenses 2 and/or their axes A are arranged preferably symmetrically with respect to the longitudinal extension L of the target 4 and/or have an offset or distance E from the respective end of the target 4 in the axial direction or X direction.

In particular, the lenses 2 are located in an end region or its vicinity of the respective target 4, as indicated in FIGS. 1 and 2.

The diagram in FIG. 3 qualitatively illustrates the rate R of removal of the target 4 during coating as a function of the axial position or X position. In this way a rate profile P of the rate R over X, therefore in the direction of the longitudinal extension L of the target 4, arises.

The rate profile P has a first at least essentially homogeneous region B1 in the middle axial region of the target 4 homogeneous. The rate R in the first region B1 is thus at least essentially constant and/or varies along the axial extension of the target 4 in this region B1 at best only very little, in particular less than 5%. Preferably, “essentially constant” according to the invention means that the rate R along the longitudinal axis L, here in the region B1, varies by less than 5%.

The rate profile P furthermore has a second, non-homogeneous or inhomogeneous region B2. In this second region B2 the rate R varies very strongly, increases strongly in particular towards the end of the target 4, especially preferably by more than 10%.

The rate R of removal of the target 4 which increases towards the end of the target 4 and/or the respective magnet arrangement 5 in the second region B2 can be explained by the magnetic field strength which is increased in the end region.

FIG. 3 shows that a second region B2 in the indicated sense adjoins the first region B1 on both sides and/or towards the respective end of the target 4.

The lenses 2 are preferably each arranged—here in the axial extension L and/or X direction over the target 4—such that the lens 2 is located both in the first region B1 and in the second region B2 or overlaps them. Especially preferably, the middle and/or axis A of the respective lens 2 is located in the vicinity of the transition from the first region B1 to the second region B2. The deviation of the axis A from this transition is preferably less than 30%, in particular less than 20%, especially preferably less than 10% of the lens diameter.

It has been shown that the aforementioned arrangement of the lens 2 both in the first region B1 and in the second region B2 in consideration of the rotation of the lens 2 around the axis A during coating can yield an especially uniform coating.

The axis A around which the lens 2 rotates during coating is preferably stationary or fixed relative to the target 4 or the sputtering source 3 or axis D of rotation.

In particular, a linear movement and/or a center-of-gravity movement such as a circular movement between the sputtering source 3 and/or the target 4 and/or the axes D of rotation on the one hand and the lens 2 or lenses 2 to be coated and/or the axes A on the other is avoided or precluded. This is conducive to an especially simple structure.

The offset or distance E of the axis A of rotation of the lens 2 from the respective end of the target 4 is preferably more than 1.0 times or 1.5 times the lens diameter and/or the target diameter.

The distance E is preferably fixed. Optionally, an adaptation or adjustment of the distance E of the axis A of rotation of the lens 2 from the respective end of the target 4 takes place as a function of the diameter and/or the curvature and/or shape of the lens 2 or surface which is to be coated.

The (vertical) distance Z of the lens 2 from the assigned target 4 is indicated in FIG. 1 and is preferably more than 1.0 times the lens diameter or the target diameter.

The (vertical) distance Z of the lens 2 from the assigned target 4 is preferably more than 60 mm and/or less than 150 mm, in particular less than 130 mm.

The distance Z is preferably fixed. Optionally, an adaptation or adjustment of the (vertical) distance Z of the lens 2 from the assigned target 4 takes place as a function of the diameter and/or the curvature and/or shape of the lens 2 or surface which is to be coated.

The target diameter is preferably about 70 to 130 mm.

Preferably, the (outside) diameter of the target is at least essentially constant over the length.

The target 4 is thus preferably made cylindrical or hollow cylindrical.

The axes A of two lenses 2 which are assigned to a common target 4 run preferably in one common plane and in particular parallel to one another.

The axes A run preferably transversely or perpendicular to the target plane and/or common plane of the axes D of rotation and/or to the axis D of rotation of the assigned target 4.

In their common plane the axes A can also be inclined relative to one another, in particular at one another or to the outside or away from one another. Accordingly, the lenses 2 are then brought closer to one another or moved away from one another, in particular optionally so that the surfaces to be coated of the two lenses 2 are somewhat tilted towards one another and/or point somewhat more towards the middle of the respective target 4. Accordingly, the angle N of incline of the axes A to the axes D of rotation can deviate from the preferred 90°, as shown in FIG. 3, and can be less than 90°, for example about 70° to 85°, or more than 90°, for example about 95° to 110°.

The angle N of incline is preferably fixed. Especially preferably, however, an adaptation or adjustment of the angle N of incline optionally takes place as a function of the diameter and/or the curvature and/or shape of the lens 2 or surface which is to be coated.

The axis A of rotation of the lens 2 can also be shifted in the Y direction, thus in a direction transversely to the axis D of rotation in the horizontal direction and/or towards the middle between the two axes D of rotation of the targets 4, in particular so that an offset or distance V forms between the lens axis A and the assigned target axis D, as indicated in FIG. 1 for the lens 2 which is located on the right side (of course the same also applies preferably to the lens 2 which is located on the left side). The offset or distance V is preferably less than 20%, in particular less than 10%, of the lens diameter and/or target diameter.

The distance V is preferably fixed. Optionally, an adaptation or adjustment of the distance V between the lens axis A and the assigned target axis D takes place as a function of the diameter and/or the curvature and/or shape of the lens 2 or surface which is to be coated.

Preferably the angle N of incline and/or the location of the axes A or the distances E, V and/or Z are established by the carrier 10.

The gas supply 9 is preferably located underneath the sputtering sources 3 and/or targets 4 and/or in between, especially preferably in the middle plane M of the device 1 and/or coating chamber 7.

The gas supply 9 is preferably designed tubular and/or rod-like and/or is provided with gas outlets which point up and/or which are located preferably in a row.

The sputtering cloud S which arises during coating, i.e. the sputtered target material, is guided at least essentially in a desired direction by means of the already mentioned magnetic field and/or the magnet arrangement 5 in each case. This primary direction H of propagation of the sputtering cloud S which is indicated by the broken line in FIG. 1 can be influenced, in particular can be established, by corresponding arrangement or orientation of the magnet arrangement 5.

In the illustrated example, the primary direction H in the plane of the section perpendicular to the axes D of rotation and/or of the two targets 4 is preferably tilted to one another and/or by the angle W (starting from a parallel orientation). Preferably, the angle W can be set or adapted, in particular by corresponding adjustment or triggering of the magnet arrangements 5.

The angle W is preferably less than 10°, in particular less than 7°, especially preferably less than 5°.

As already indicated, the primary directions H of the two sputtering clouds S can also run parallel to one another and/or perpendicular to the extension plane of the target 4 and/or plane with the axes D of rotation.

Preferably, the primary directions H run vertically upward or contain one such direction component. Alternatively, there is a horizontal alignment of the primary directions H. The arrangement of the lenses 2 and sputtering sources 3 and/or targets 4 must then be chosen of course accordingly.

Preferably, the lenses 2 in the device 1 according to the proposal and in the method according to the proposal are each held both in the first region B1 and in the second region B2 and rotated in doing so. This can yield an especially uniform coating.

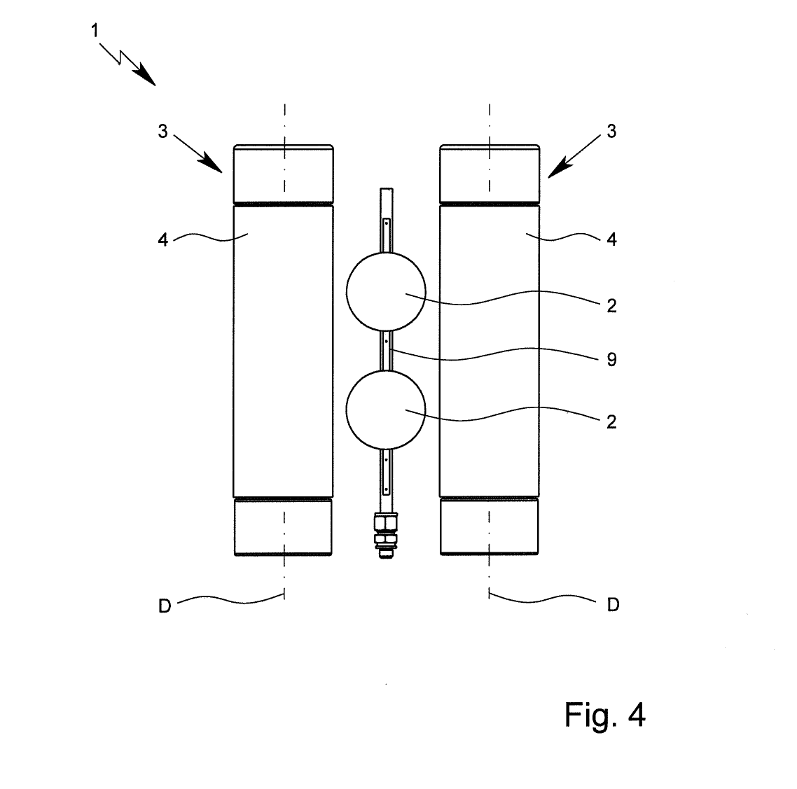

Especially preferably, the lenses 2 are coated in pairs, in particular two pairs of lenses 2 are coated at the same time. However, it is in principle also possible to coat only one pair of lenses 2 in the device 1 according to the proposal. To do this, the two lenses are then located preferably over a common target 4 and/or between the two targets 4, as shown schematically in FIG. 4 in one alternative arrangement.

Preferably, the rate profile P is not influenced or homogenized by distribution diaphragms or the like in the device 1 and/or coating chamber 7. This is advantageous in particular with respect to unwanted deposits on such diaphragms.

According to one aspect of the present invention which can also be implemented independently the outside diameter of the target 4 can vary over the axial extension or length or the longitudinal extension L of the target 4, as indicated schematically in FIG. 3 by the double-dotted broken line or target surface T.

In particular, the target 4 can be made for example thicker in the middle than on the end regions and/or for example barrel-shaped.

In the middle and/or between the axes A of rotation of the lenses 2 and/or between the regions B2 (which are forming otherwise) the outside diameter of the target 4 is preferably at least essentially constant and/or for example more than 4% larger than on the ends of the target 4, as indicated in FIG. 3.

In particular, the outside diameter can also be reduced or can decrease only towards the end regions of the target 4, in particular in the regions B2 and/or only in the end region by less than 25% of the length L of the target 4.

In principle, the outside diameter in the longitudinal extension L can have any shape, if necessary also (partially) convex, concave or corrugated.

Preferably, the outside diameter of the target 4 varies by more than 4% over the longitudinal extension or length L of the target 4.

Especially preferably, the rate profile P is modified in the desired manner, for example made (more) uniform, by variation of the outside diameter over the length L of the target 4.

Alternatively or in addition to the variation of the outside diameter, the magnetic field and/or the magnetic field strength of the magnet arrangement 5 can also vary over the length L of the target 4 and/or of the sputtering source 3, in particular can decrease towards the end and/or can be greater in the region of the middle, in particular by more than 4%, in order to modify the rate profile P in the desired manner, especially preferably to make it (more) uniform, and/or to achieve a certain or desired and/or at least essentially constant strength of the magnetic field on the target surface, in particular also in consideration of the optionally varying outside diameter, even when the outside diameter of the target 4 varies.

The aforementioned variations of the outside diameter and/or magnetic field preferably make the rate profile P (more) uniform, modifies or fixes it such that in particular in consideration of the positioning of the lens 2 to be coated relative to the target 4 (for example the location of the axis A of rotation of the lens 2 and the distance of the lens 2) and/or in consideration of the shape and/or the size of the surface of the lens 2 which is to be coated, a desired coating of the lens 2 can be achieved or is achieved, which coating is in particular uniform or defined in some other manner, or which coating is optionally also nonuniform, for example increases or decreases towards the edge.

The lenses 2 rotate preferably centrically around the respective axis A, in particular with respect to the geometrical center of the lens 2.

According to one version which is not shown, the lenses 2 can optionally also rotate and/or be clamped eccentrically with respect to the axis A of rotation. The eccentricity is here preferably smaller than the radius of the lens 2, and can optionally also be larger.

In particular, the axis A of rotation thus intersects the respective lens 2.

The axis A runs preferably perpendicular to the main plane of the respective lens 2.

Each of the lenses 2 can preferably be rotated around its own axis A.

The axis A runs preferably transversely, optionally perpendicular, to the longitudinal extension or axis D of rotation of the assigned target 4.

In particular, the axis A of rotation of the respective lens 2 intersects the assigned target 4, as indicated in FIG. 1, or optionally, the longitudinal axis or axis D of rotation of the assigned target 4.

The lens 2 during coating and/or rotation preferably always points toward the assigned target 4 or the two assigned targets 4 with its side to be coated.

Preferably, the axis D of rotation of the respective target 4 runs perpendicular to any or at least one surface normal of the lens 2 or surface which is to be coated.

The surface normal of the optical or geometrical center of the lens 2 can be tilted to the axis A of rotation or axis D of rotation.

The lens centers are preferably arranged symmetrically to the respective target 4 in the X direction and/or longitudinal extension of the target 4.

The lenses 2 which are to be coated and/or their geometrical or optical centers are preferably arranged at least essentially in a common plane, this plane running especially preferably parallel to the extension plane of the sputtering sources 3 and/or targets 4 or axes D of rotation.

With the device 1 according to the proposal and/or the method according to the proposal or the use of tubular parallel targets 4 according to the proposal for coating of lenses 2, preferably coating rates from 0.001 to 20 nm/s, in particular 0.005 nm/s to 2.5 nm/s, are achieved.

The rotational velocity of the lenses 2 is preferably 10 to 200 rpm, in particular about 40 to 120 rpm.

The diameter of the lenses 2 is preferably about 40 to 85 mm.

The rotational velocity of the target 4 is preferably about 3 to 30 rpm.

Preferably, the rotational velocity of the lenses 2 is greater than that of the target 4, in particular it is more than 2 or 3 times the rotational velocity of the target 4.

The coating time is preferably about 4 to 7 min.

The device 1 according to the proposal or the method according to the proposal or the use according to the proposal is preferably used to apply one or more antireflection layers.

According to the proposal, in particular reactive coating takes place, wherein by corresponding supply of reactive gas, for example nitrogen, hydrogen and/or oxygen, to the working gas (noble gas), in particular argon, the target material is able to react with it and a desired coating on the lens 2 can form.

During coating, the device 1 and/or the coating chamber 7 is preferably evacuated to a pressure of about 0.005 Pa to 0.5 Pa.

In particular, a device 1 and methods for coating of lenses 2 are proposed, wherein lenses to be coated are arranged in pairs over parallel tubular targets 4 such that they each overlap both a homogeneous and an inhomogeneous removal region B1, B2 of the target 4 and wherein the lenses 2 rotate so that an especially uniform coating can be achieved.

1-20. (canceled)

21. A device for coating of lenses by means of sputtering, comprising:
means for producing sputtering of material from at least one elongated or tubular target and
a carrier for holding at least one lens to be coated, the lens being rotatable on the carrier around an axis which intersects the lens,
wherein the lens is arranged relative to the target both in a first region of the target, removal of material from which is at least essentially homogeneous in a longitudinal extension of the target, a rate of the removal varying by less than 5%, and in a second region of the target, removal of material from which is inhomogeneous in the longitudinal extension of the target at which a rate profile of removal occurs during coating, the lens being rotatable around a stationary axis relative to the target; and
wherein the target has an outside diameter which varies over a longitudinal extension of the target and which decreases in a direction towards ends thereof.

22. The device according to claim 21, wherein the carrier is changable together with at least two lenses.

23. The device according to claim 21, wherein the carrier holds the lens located off-center over the target.

24. The device according to claim 21, wherein the carrier holds the lens in a stationary position relative to the target.

25. The device according to claim 21, wherein two lenses are positioned symmetrically with respect to the longitudinal extension of the target.

26. The device according to claim 21, wherein the carrier holds two lenses over opposite end regions of the target.

27. The device according to claim 21, wherein the target is rotatable.

28. The device according to claim 21, wherein said at least one elongated or tubular target comprises two elongated or tubular targets which run parallel to one another, the targets being operable alternately as a cathode and an anode.

29. The device according to claim 28, wherein four lenses are located are located over the targets, two lenses over each of the two targets.

30. The device according to claim 28, wherein the axes of the lenses run transversely to a common plane of the targets.

31. The device according to claim 21, wherein the carrier holds a plurality of lenses rotatably coupled.

32. The device according to claim 21, wherein the carrier holds a plurality lenses which are rotatable around their own axes.

33. The device according to claim 21, further comprising a drive, wherein the carrier is automatically coupled with the drive upon insertion of the carrier of the carrier into the device.

34. The device according to claim 21, wherein the carrier holds the lens with at least one of a stationary center of gravity and in a centrically rotatable manner.

35. The device according to claim 21, wherein the axis of the lens intersects the target.

36. Method for coating of curved surfaces of lenses by means of sputtering of a target, comprising:
producing coating by sputtering with a rate profile of removal of an elongated or tubular target in a longitudinal extension of the elongated or tubular target, the rate profile having a first, at least essentially homogeneous region which varies by less than 5%, and also a second heterogenous region, at least one lens to be coated being held both in the first and in the second region while being rotated around a stationary axis.

37. Method according to claim 36, wherein lenses are coated in pairs.by means of magnetron sputtering.

38. A method for coating of curved surfaces of lenses by means of sputtering using two tubular parallel targets, comprising:
arranging four lenses in pairs over the two targets. and
rotating the lenses around their own axes while performing sputtering.

39. The method according to claim 38, comprising the further step of operating the targets alternately as a cathode and an anode with direct current.

40. A method for coating of curved surfaces of a lens by means of sputtering, comprising:
providing an elongated target having an outside diameter which varies over a longitudinal extension of the target and
rotating the target to achieve an at least essentially homogeneous rate profile of removal of the target in the longitudinal extension and a uniform coating on the lens.

41. The method of coating according to claim 40, comprising the further step of arranging the lens relative to the target both in a first region of the target, removal of material from which is at least essentially homogeneous in a longitudinal extension of the target, a rate of the removal varying by less than 5%, and in a second region of the target, removal of material from which is inhomogeneous in the longitudinal extension of the target at which a rate profile of removal occurs during coating, and rotating the lens around a stationary axis relative to the target.
